(19) United States
(12) Patent Application Publication
(10) Pub. No.: US 2025/0335666 A1
(43) Pub. Date: Oct. 30, 2025

(54) METHOD FOR PRODUCING AN ANOMALY DETECTION MODEL, AND ASSOCIATED MICROCONTROLLER AND COMPUTER PROGRAM PRODUCT

(71) Applicant: STMicroelectronics International N.V., Geneva (CH)

(72) Inventors: Mohamed Ali Moussa, Toulon (FR); Julian Ettarian, Toulon (FR)

(21) Appl. No.: 19/174,581

(22) Filed: Apr. 9, 2025

(30) Foreign Application Priority Data
Apr. 26, 2024 (FR) FR2404380

(51) Int. Cl. G06F 30/27

(52) U.S. Cl. CPC G06F 30/27

(57) ABSTRACT

A method implemented by computer for producing an anomaly detection model comprises obtaining normal data, generating abnormal data using the normal data, the generating comprising an introduction of non-plausible values into the normal data, producing an anomaly detection model with a machine learning algorithm configured to generate an anomaly detection model, using the normal data and the generated abnormal data.

### CROSS-REFERENCED TO RELATED APPLICATIONS

This application claims the benefit of French Patent Application No. 2404380, filed on Apr. 26, 2024, which application is hereby incorporated herein by reference.

### TECHNICAL FIELD

Embodiments and implementations relate to the production of an anomaly detection model.

### BACKGROUND

Anomaly detection in a physical system is a technique used for identifying data that significantly differ from data representing normal behavior of the physical system. These data are often referred to as “anomalies” or “outlier values.”

Anomaly detection finds an interest in many applications. Some applications use a microcontroller deployed in the physical system to be monitored. Such a microcontroller is then configured to implement anomaly detection.

Anomaly detection implemented by a microcontroller makes it possible to monitor in real time to detect abnormal behaviors in a physical system using data acquired by at least one sensor in this system. This technique can be used in the context of predictive maintenance applied to a variety of fields such as automobile, aerospace, energy, manufacturing production, health monitoring and many others.

In the context of anomaly detection, a microcontroller generally uses a model which is adapted to learn the normal behavior of a system with data collected by at least one sensor in the system. This can be referred to as incremental learning, in particular if the data are not saved and the leaning is performed based on the collected data flow.

If the collected data differ too much from the expected data, this may indicate an anomaly or a malfunctioning in the system. In this case, an alert can be triggered to warn an operator of the system.

This type of anomaly detection technique therefore makes it possible to warn of breakdowns and failures of the system. This makes it possible to improve the reliability and safety of the system.

The model used for performing anomaly detection is advantageously previously calibrated (i.e. specifically adapted) for the type of detection of the use case; the model thus pre-calibrated being capable of being obtained with a machine learning algorithm. A computing means having a greater processing capacity than the microcontroller implementing the model, such as a server or a personal computer, may be used to implement the machine learning algorithm for obtaining the model.

In particular, the machine learning algorithm is configured to generate a model for anomaly detection using learning data representing a normal behavior of the system, and ideally also using learning data representing an abnormal behavior of the system.

The anomaly detection model is produced so as to be able to discriminate a normal behavior and an abnormal behavior of the system. The anomaly detection model can then be used by a microcontroller deployed in the physical system to be monitored.

However, acquiring learning data representing abnormal behaviors may prove to be difficult, expensive, or even impossible in some cases. This is because it is often a disincentive to break machines in order to intentionally generate anomalies in a system to obtain outlier data.

Consequently, in practice one-class (or “1-class”) models are produced without anomaly data, by the machine learning algorithm, such that the “1-class” anomaly detection models thus obtained are effective and reliable in detecting a normal behavior, but may be less effective and less reliable in the case of abnormal behavior.

In other words, in models thus conventionally obtained, there is a risk of inaccurate results in behavior qualification, which is greater in the case of abnormal behavior of the measured system.

Therefore, there is a need to improve the performance of anomaly detection models, in particular in the case of abnormal behavior, without for all that receiving outlier data from an anomaly in a system (or without receiving a greater quantity of outlier data).

### SUMMARY

In this regard, implementations propose generating “simulations” of abnormal data based on normal nominal data, for example by distorting normal signals, the data being used by a machine learning algorithm to generate the anomaly detection model.

According to one aspect, a method implemented by computer for producing an anomaly detection model is proposed, the method comprising obtaining normal data, generating abnormal data using the normal data, comprising an introduction of non-plausible values into the normal data, and producing an anomaly detection model with a machine learning model configured to generate an anomaly detection model, using the normal data and the abnormal data.

The machine learning model may be configured to locate the most suitable model for anomaly detection with respect to the data provided, for example from a set including basic models and all possible combinations of the basic models.

Producing the most suitable model for anomaly detection may comprise a phase of training the models of the set, using learning data including normal data; and phase of evaluating the models thus learned, using test data including other normal data and the abnormal data.

In other words, according to an implementation, the machine learning algorithm for producing the anomaly detection model comprises a phase of training models with learning data including a portion of the normal data, and a phase of evaluating the models with test data comprising another portion of the normal data and the abnormal data.

The model thus produced is thus specifically adapted to learn the normal behavior of a system with data collected by at least one sensor in the system. This may be referred to as incremental learning. This makes it possible to learn the specificities of each environment observed.

The model thus produced may be deployed in a microcontroller to monitor a physical system corresponding to the normal data used for its production, the model being consequently specifically adapted to monitoring the system.

The model thus produced is for example provided to implement incremental learning with the data from monitoring the system, on a basis optionally benefitting from prior knowledge of the learning data used for producing the model.

For example, the detection model is adapted to classify data that it receives as an input as being normal data or as being abnormal data. These data may come from an acquisition made in the physical system to be monitored. For example, the data may be signals measured by an accelerometer or a microphone in a rotary machine.

According to an implementation, the non-plausible values are calculated according to the standard deviations and means of the values of the normal data, on the set of normal data.

According to an implementation, each non-plausible value is calculated so as to obtain a deviation from the mean greater than a factor of the standard deviation (for example greater than 3 times the standard deviation), at the position of the non-plausible value calculated.

According to an implementation, the introduction of non-plausible values into the normal data comprises an amplification of the values of the normal values by a value factor centered at random on 1 according to the uniform lay if the power of the signal communicated in the normal data is greater than a threshold, or an addition of a Gaussian noise to the values of the normal data if the power is lower than the threshold.

According to an implementation, the generation of abnormal data comprises, for each abnormal data item, the introduction of the non-plausible values into a local portion of the content of a normal data item, and an unchanged copy of the rest of the content of this normal data item.

According to an implementation, the local portion corresponds to a frequency sub-band in the spectrum of the content of the normal data item.

According to an implementation, the non-plausible values are introduced at random on a fraction (for example one-third, or between one-half and one-quarter) of the values of the local portion of the content of the normal data item.

According to an implementation, obtaining the normal data comprises an acquisition of signals in the time domain, and a transformation of the signals in the frequency domain (for example by means of a fast Fourier transform).

For example, the method further comprises production of a computer program product for detecting anomalies comprising instructions which, when the program is executed by a computer, cause the latter to implement the detection model.

According to another aspect, an anomaly detection method implemented by computer is also proposed, comprising an implementation of the anomaly detection model produced with a method as defined hereinabove.

In particular, the anomaly detection method corresponds to an inference phase for using the detection model produced, for example deployed in a microcontroller monitoring a physical system.

For example, the monitoring model may furthermore be configured to implement incremental learning of the normal behavior of the system, with data collected in the course of the implementations of the monitoring of the physical system.

For example, the monitoring model may optionally receive initial knowledge, from the data used when producing the model, in particular normal learning data of the training phase. Otherwise, the model may be blank and be provided to refine its functionality by incremental learning only.

According to another aspect, a computer program product for producing an anomaly detection model is also proposed, comprising instructions which, when the program is executed by a computer, cause the latter to implement a method for producing an anomaly detection model as defined hereinabove.

According to another aspect, a computer program product for detecting anomalies is also proposed, comprising instructions which, when the program is executed by a computer, cause the latter to implement an anomaly detection method as defined hereinabove.

According to another aspect, a microcontroller is also proposed comprising a non-transitory memory comprising a computer program product for detecting anomalies as defined hereinabove, and a processing unit or processor configured to execute the computer program product.

### BRIEF DESCRIPTION OF THE DRAWINGS

Other advantages and features of the invention will become apparent upon examining the detailed description of non-limiting embodiments and implementations of the invention, and from the accompanying drawings in which:

FIG. 1 illustrates a method for producing an anomaly detection model;

FIG. 2 illustrates an example of a normal data set after the transformation step;

FIG. 3 illustrates a first step of the generation of the method for anomaly detection;

FIG. 4 illustrates examples of abnormal data generated using normal data; and

FIG. 5 illustrates a microcontroller implementing the method for anomaly detection.

### DETAILED DESCRIPTION OF ILLUSTRATIVE EMBODIMENTS

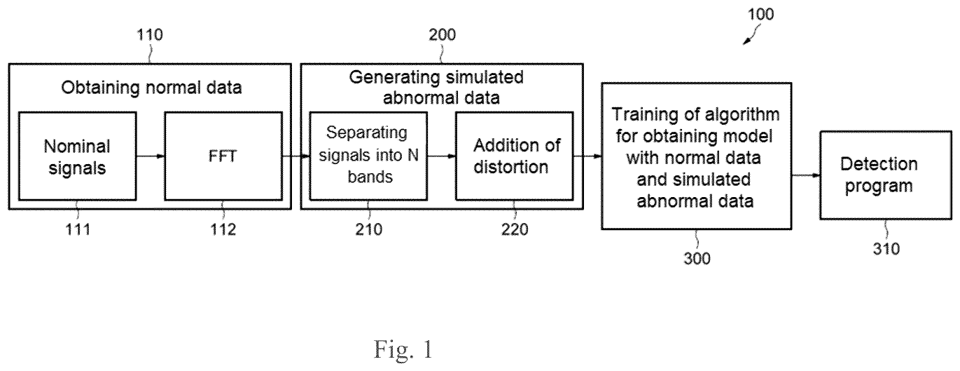

FIG. 1 illustrates a method for producing an anomaly detection model 100. The method 100 is implemented by computer, for example a desktop computer or a computer supplied by an external server, where the computer comprises a non-transitory memory storing instructions that are executed by a processor coupled to the non-transitory memory in the computer.

The method for producing the anomaly detection model 100 may for example be provided in a functionality of a computer program product for producing an anomaly detection model comprising instructions which, when the program is executed by a computer, cause the latter to implement a method for producing an anomaly detection model 100 as described hereinafter.

The method for producing the anomaly detection model 100 may for example be provided in a functionality of development studio software in this regard.

The development studio provides for example an interface that is simple and user-friendly for developers, and is provided to generate models, in particular anomaly detection models, but also outlier value detection, classification and regression models.

These models may be combined and sequenced to create a complete artificial intelligence solution: detection of anomalies or outlier values to detect a problem on equipment, classification to identify the source of the problem, and regression to extrapolate the information and provide an actual overview to a maintenance team.

The input signals may be for example signals representing vibrations, pressures, sounds, times of flight, or a combination of several signals.

The method for producing an anomaly detection model 100 comprises obtaining normal data 110, i.e. training data representing a normal behavior of a system, in the manner of 1-class classification techniques.

However, the method 100 advantageously comprises a method 200 for generating abnormal data using the normal data obtained for training.

The abnormal data thus generated make it possible to “simulate” training data representing an abnormal behavior of the system, in the manner of multi-class classification techniques, without for all that requiring the user to provide abnormal data.

This is because the acquisition of actual data representing abnormal behaviors may be difficult, expensive, or impossible in some cases in particular if it is necessary to break machines in order to intentionally generate anomalies.

The anomaly detection model is then advantageously obtained by implementing 300 a machine learning algorithm configured to generate an anomaly detection model, with learning and test data including the normal data 111 and the abnormal data 200 thus simulated using the normal data.

Indeed, the machine learning model 300 may be configured to locate the most suitable model for anomaly detection with respect to the data provided, for example from a set including basic models and all possible combinations of basic models.

Producing the most suitable model for anomaly detection may comprise a phase of training the models of the set, using learning data including a portion of the normal data 111; and a phase of evaluating the models thus learned, using test data including another portion of the normal data 111 and the abnormal data 200.

The anomaly detection model thus produced may for example be realized by a computer program product for detecting anomalies 310 comprising instructions which, when the program is executed by a computer (for example a microcontroller), cause the latter to implement the anomaly detection method, such as for example a compiled program ready to be deployed in a microcontroller capable of executing it.

Generating abnormal data 200 using the normal data comprises summarily an introduction of a distortion in the content of the normal data obtained, for example by adding non-plausible values 220 in the normal data.

The non-plausible values are calculated accounting for statistical and/or physical considerations of the normal data, in a non-arbitrary manner making it possible to approximate the fineness and subtlety of the differences between the normal and abnormal behaviors of real cases.

In practice, generating the model with abnormal data simulated by the method for generating abnormal data 200 is particularly well-suited to vibration signals from an accelerometer, measured on rotary machines.

Advantageously from a practical and analytical point of view, the distortion is introduced in the frequency domain.

Thus, the step of obtaining the normal data 110 may advantageously comprise an acquisition of normal signals in the time domain 111, followed by a transformation of the signals into the frequency domain 112.

The acquisition 111 may correspond to receiving or reading data, the content of which expresses the nominal signals, produced externally for example via a database.

Optionally, the acquisition 111 may correspond to measuring the nominal signals, instantaneously on an actual system.

The transformation in the frequency domain 112 is for example performed in a conventional manner known per se with a fast Fourier transform (FFT).

During the FFT transformation in the frequency domain 112, the frequency spectrum obtained may optionally be formally adapted, for example so as to center the data on o, removing the mean.

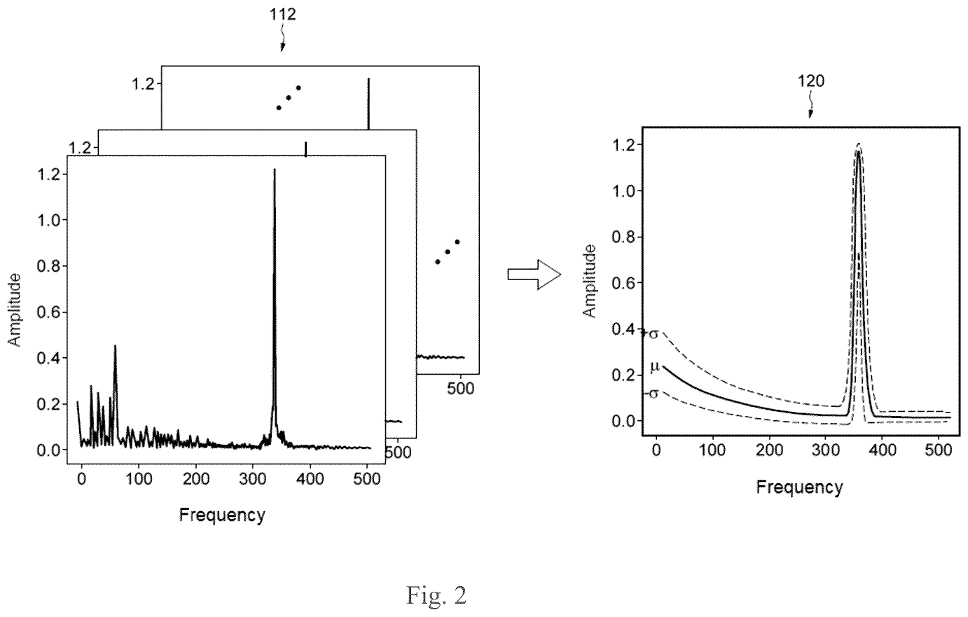

Furthermore, at this step 112, the spectral value moduli may be calculated, so as to calculate the power of the nominal signals, or a power spectral density of the nominal signals. Reference is now made to FIG. 2.

FIG. 2 illustrates an example of a normal data set, after the transformation step 112. Each normal data item is thus represented by a graph plotting the frequency spectrum of the nominal signal.

Advantageously for implementing the distortion introduced into the normal data, and in particular for quantifying the non-plausible values 220, statistical indicators 120 are calculated on the set of nominal signals thus obtained 112.

The statistical indicators 120 include for example the mean value μ and the standard deviation +σ, −σ of the amplitudes on the frequencies of the spectrum of all the signals 112 of the set.

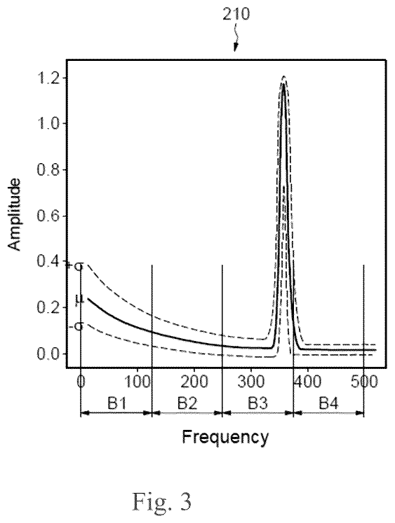

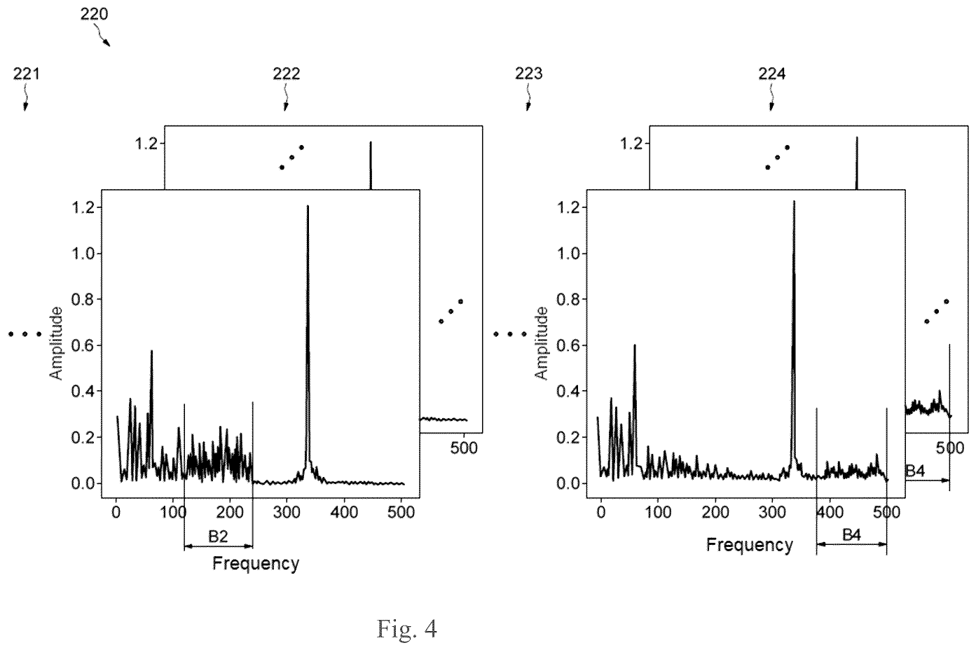

Reference is now made to FIGS. 3 and 4 to describe an advantageous implementation of generating abnormal data 200 using the normal data, comprising the introduction of non-plausible values 220 into the normal data.

FIG. 3 illustrates a first step 210 of the generation 200 of the method 100 (FIG. 1), wherein the frequency spectra of the nominal signals are separated into several “N” frequency sub-bands.

For example, the frequency spectrum of the normal data into 4 sub-bands of equal sizes B1, B2, B3, B4.

And advantageously, generating each abnormal data item 200 comprises the introduction of the non-plausible values into a local portion B1, B2, B3, B4 of the content of a normal data item. Each abnormal data item moreover includes an unchanged copy of the rest of the content of the normal data item.

Each local portion therefore corresponds to one of the N (for example N=4) frequency sub-bands B1, B2, B3, B4 of the spectrum contained in the normal data item.

Thus, it will be noted that with a single normal data item 112 (a single nominal signal 111), it is possible to generate N (for example N=4) abnormal data items.

Furthermore, the non-plausible values 220 may be introduced at random on a fraction of the values of the local portion of the content of the normal data item.

It will be noted that the data are necessarily sampled since they consist of measurements saved in a digital format, and therefore each sub-band includes a finite number of values at respective positions (in this case, the position being the frequency, the value being the amplitude).

For example, the fraction is located between one-half (½) and one-quarter (¼), for example one-third (⅓), such that only one value out of three is replaced by a non-plausible value, whereas the other values (two out of three, ⅔) of the modified frequency sub-band B1-B4 remain unchanged.

This makes it possible to generate discrete distortions with respect to the normal values, which makes it possible to refine the machine learning for producing the detection model which is also more refined and therefore more reliable.

This is because introducing overly “visible” or overly discriminatory distortions with respect to the normal data item could generate a detection model trained to detect pronounced and non-subtle differences which would therefore be less effective.

In sum, the implementations described with reference to FIG. 3, relating to the introduction of non-plausible values into a local portion only of the normal data item, make it possible advantageously to generate abnormal data relatively similar to the normal data.

FIG. 4 illustrates examples of the abnormal data 221, 222, 223, 224 thus generated using the normal data 112.

Each normal data item 112 makes it possible to generate N (N=4) distinct abnormal data items 221, 222, 223, 224, each corresponding to the introduction of the non-plausible values into one of the N (N=4) frequency sub-bands 210.

As mentioned above, the non-plausible values may be calculated accounting for statistical indicators of the normal data, for example according to the standard deviations σ and the means μ of the normal data spectrum values, considered on the normal data set 112.

It is reminded that the non-plausible values are positioned at random on for example one-third of the values of the respective sub-band B1-B4.

In this regard, for example each non-plausible value is calculated so as to obtain a deviation from the mean μ greater than a factor of the standard deviation σ, at the position in the frequency spectrum that the non-plausible value thus calculated will take.

In other words, a non-plausible value is constructed at a given frequency (position), by assigning a greater amplitude than the mean value μ at this frequency of at least k times the standard deviation of the values at this frequency on the normal data set (where for example k=3).

Alternatively, and as mentioned above, the non-plausible values may be calculated by accounting for physical considerations on the normal data 112, such as the consideration of the power of the signal contained in the normal data, for example the power spectral density at the corresponding frequency.

In this regard, for example, the introduction of non-plausible values 220 into the normal data comprises an amplification of the nominal signal (i.e., an amplification of the normal data values), by a factor centered at random on 1, for example between 0.5 and 1.5, according to the uniform law, in respectively one of the N (N=4) frequency sub-bands.

Advantageously, this random nominal signal amplification operation may be performed if the power of the signal is greater than a threshold in the modified band. Otherwise, if the power of the signal is strictly less than the threshold in the modified band, the introduction of the non-plausible values 220 into the normal data may comprise adding a Gaussian noise in the normal data belonging to the sub-band.

The positioning of the threshold may for example depend on each practical scenario, according to the nominal powers and the disparity or homogeneity of the powers of the signals measured, and/or other practical considerations.

The random amplification operation centered around 1 makes it possible to construct non-plausible values and having nonetheless differences contained and measured on high-power nominal signals, but may have an overly weak effect for low-power nominal signals (lower than the threshold).

Conversely, adding a Gaussian noise makes it possible to introduce a random character into the low-power signals, but may have an overly strong and overly distinctive effect in high-power nominal signals (greater than the threshold).

In summary, the implementations described with reference to FIG. 4, relating to the quantification of the non-plausible values introduced directly into the normal data, make it possible advantageously to generate data sufficiently different from the normal data to make an improvement in the model generation.

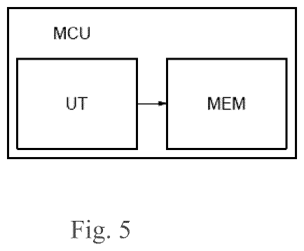

FIG. 5 illustrates a microcontroller MCU wherein the anomaly detection model thus produced has been deployed, it is a microcontroller MCU configured to implement the method for anomaly detection.

The microcontroller can be integrated in a system for which monitoring of operating anomalies is required. The microcontroller can be configured to receive data acquired by a sensor of the system, for example a microphone or an accelerometer. These acquired data then represent the operation of the system. For example, the physical system may be a rotary machine.

The microcontroller MCU comprises a processor or processing unit UT and a non-transitory memory MEM.

The non-transitory memory MEM comprises a computer program 310 (FIG. 1) comprising instructions which, when they are implemented by the processor or processing unit UT of the microcontroller result in the latter implementing the anomaly detection model 310 as obtained after the method 100 for producing the model 310 described above with reference to FIG. 1 and FIGS. 2 to 4.

This computer program 310, thus deployed in the microcontroller MCU, can be executed by the processor or processing unit UT to implement a detection of anomalies from data to be monitored.

This may for example be applied to the field of predictive maintenance of rotary machines by monitoring vibrations by means of the microcontroller MCU and an accelerometer.

As another example, a company is logging vibration data to detect anomalies in their industrial fan with a 3-axis accelerometer. They are able to collect the normal functioning of the fan, but generally it would cost too much money to create defects to log them.

To train an anomaly detection model for embedding on a microcontroller, they should have both normal and abnormal examples of vibration of the fan. An embodiment generates plausible anomalies based on the normal data for use in such a model.

As yet another example, another company is logging vibration data to detect anomalies in their pump. For the same reason, collecting data of the normal behavior is feasible, but creating defects for logging generally is too costly. Again, an embodiment additionally can generate plausible abnormal data, along with the normal data, to train an anomaly detection model for the pump and deploy it on microcontrollers.

In these embodiments, one or more nominal vibration data examples are used to generate abnormal vibration data. Embodiments are generally useful to train models for microcontrollers, although embodiments may be used solely to generate abnormal data from normal data, which then may be used in whatever manner the user desires.

It will be possible for example in this regard to collect normal data with the microcontroller, generate “simulated” abnormal data using the collected nominal data set, train an anomaly detection model with a development studio, based on the data collected and the data generated, and deploy the model on the microcontroller MCU.

Optionally, it may be envisaged to update the model deployed on the microcontroller MCU, by training performed directly on the microcontroller MCU with the data collected during “practical” implementations of the detection model.

Indeed, the monitoring model may be configured to implement incremental learning of the normal behavior of the system, with the data flow collected in the course of the implementations of the monitoring of the physical system.

Moreover, during its deployment, the monitoring model may initially receive initial knowledge, or be blank. The initial knowledge is for example obtained from the data used when producing the model, in particular normal learning data of the training phase.

Finally, in summary, generating the “simulated” abnormal data based on the normal data comprises transforming the nominal data in the frequency domain with an FFT, and dividing each signal into a specific number of equal sub-bands. In a first alternative, the generating further comprises calculating the standard deviation and the mean at all frequencies, and distorting a specific proportion of each band by assigning it non-plausible values calculated based on the mean and the standard deviation, while leaving the other sub-bands unchanged. In a second alternative, the generating further comprises calculating the power (modulus) of the frequency signal, and, if the power of the signal is greater than a threshold, amplifying normal data values by a random factor centered on 1 according to a uniform law, or, if the power of the signal is lower than the threshold, adding a Gaussian noise to the normal data values.

The abnormal data thus generated are then advantageously used, in addition to the normal data, to train the model generation algorithm, for example in a development studio.

What is claimed is:

1. A method implemented by a computer, the method comprising:
obtaining normal data;
generating abnormal data using the normal data, the generating comprising introducing non-plausible values into the normal data; and
producing an anomaly detection model, with a machine learning algorithm configured to generate the anomaly detection model, using the normal data and the abnormal data.

2. The method according to claim 1, wherein the machine learning algorithm comprises:
a first phase of training models with learning data including a portion of the normal data; and
a second phase of evaluating the models with test data comprising another portion of the normal data and the abnormal data.

3. The method according to claim 1, further comprising calculating the non-plausible values according to standard deviations and means of values of the normal data.

4. The method according to claim 3, further comprising calculating each non-plausible value so as to obtain a deviation from a respective mean greater than a factor of a respective standard deviation, at a position of the respective calculated non-plausible value.

5. The method according to claim 1, wherein the introducing the non-plausible values into the normal data comprises amplifying values of the normal data by a value factor centered at random on 1 according to a uniform law in response to a power of a signal communicated in the normal data being greater than a threshold.

6. The method according to claim 1, wherein the introducing the non-plausible values into the normal data comprises adding a Gaussian noise to values of the normal data in response to a power of a signal communicated in the normal data being lower than a threshold.

7. The method according to claim 1, wherein the generating the abnormal data comprises, for each abnormal data item, the introducing the non-plausible values into a local portion of a content of a normal data item, and an unchanged copy of a rest of the content of the normal data item.

8. The method according to claim 7, wherein the local portion corresponds to a frequency sub-band in a spectrum of the content of the normal data item.

9. The method according to claim 7, further comprising introducing the non-plausible values at random on a fraction of values of the local portion of the content of the normal data item.

10. The method according to claim 1, wherein the obtaining the normal data comprises acquiring signals in a time domain, and transforming the signals in a frequency domain.

11. The method according to claim 1, further comprising producing a computer program product for detecting anomalies, the computer program product comprising instructions that, when executed by a second computer, cause the second computer to implement the anomaly detection model.

12. The method according to claim 1, further comprising implementing, by a second computer, the anomaly detection model.

13. A computer program product comprising instructions that, when executed by a computer, cause the computer to:
obtain normal data;
generate abnormal data using the normal data, the generating comprising introducing non-plausible values into the normal data; and
produce an anomaly detection model, with a machine learning algorithm configured to generate the anomaly detection model, using the normal data and the abnormal data.

14. The computer program product according to claim 13, comprising further instructions that, when executed by a second computer, cause the second computer to implement the anomaly detection model.

15. The computer program product according to claim 13, wherein the machine learning algorithm comprises:
a first phase to train models with learning data including a portion of the normal data; and
a second phase to evaluate the models with test data comprising another portion of the normal data and the abnormal data.

16. The computer program product according to claim 13, comprising further instructions to calculate the non-plausible values according to standard deviations and means of values of the normal data.

17. The computer program product according to claim 13, wherein the introducing the non-plausible values into the normal data comprises amplifying values of the normal data by a value factor centered at random on 1 according to a uniform law in response to a power of a signal communicated in the normal data being greater than a threshold.

18. The computer program product according to claim 13, wherein the introducing the non-plausible values into the normal data comprises adding a Gaussian noise to values of the normal data in response to a power of a signal communicated in the normal data being lower than a threshold.

19. The computer program product according to claim 13, wherein the instructions to generate the abnormal data comprise, for each abnormal data item, further instructions to introduce the non-plausible values into a local portion of a content of a normal data item, and an unchanged copy of a rest of the content of the normal data item.

20. A microcontroller comprising:
a non-transitory memory comprising a computer program product; and
a processor coupled to the non-transitory memory and configured to execute the computer program product to detect anomalies using an anomaly detection model produced by a machine learning algorithm configured to generate the anomaly detection model using normal data and abnormal data, the abnormal data generated by introducing non-plausible values into the normal data.
